(19) United States
(12) Patent Application Publication
(10) Pub. No.: US 2025/0377411 A1
(43) Pub. Date: Dec. 11, 2025

(54) EARLY DIAGNOSIS APPARATUS AND EARLY DIAGNOSIS METHOD FOR FOIL BREAKAGE OF BATTERY

(71) Applicant: SK On Co., Ltd., Seoul (KR)

(72) Inventors: Woo Seop KIM, Daejeon (KR); Seung Hoon JUNG, Daejeon (KR); Du Yeon LEE, Daejeon (KR)

(21) Appl. No.: 19/224,903

(22) Filed: Jun. 2, 2025

(30) Foreign Application Priority Data
Jun. 5, 2024 (KR) 10-2024-0073848

(51) Int. Cl. G01R 31/389; G01R 27/08; G01R 31/382; G01R 31/392; G01R 31/396; H01M 10/04

(52) U.S. Cl. CPC G01R 31/389; G01R 27/08; G01R 31/382; G01R 31/392; G01R 31/396; H01M 10/04

(57) ABSTRACT

An early diagnosis apparatus for foil breakage of a battery, the early diagnosis apparatus includes a resistance measurer configured to measure an internal resistance of each of a plurality of battery cells included in a battery tray output from a battery assembly process when a point in time of an inspection start is reached after battery assembly is completed, during a pause period between a battery assembly process and a battery formation process, and a foil breakage inspector configured to calculate a delta internal resistance, based on the internal resistance received from the resistance measurer, and to inspect whether foil breakage is present in each of the plurality of battery cells, based on the delta internal resistance.

### CROSS-REFERENCE TO RELATED APPLICATION(S)

This patent document claims the priority and benefits of Korean Patent Application No. 10-2024-0073848 filed on Jun. 5, 2024, the disclosure of which is incorporated herein by reference in its entirety.

### TECHNICAL FIELD

The present disclosure relates to an early diagnosis apparatus and early diagnosis method for foil breakage of a battery.

### BACKGROUND

In general, a process of manufacturing a battery may include a battery electrode process of producing a cathode plate and an anode plate of a battery, a battery assembly process of processing and assembling the cathode plate, the anode plate, and a raw material, and a battery formation process of assigning electrical properties to an assembled battery cell.

In general, before a battery module is completed through a battery formation process, it may be necessary to detect foil breakage of each of a plurality of battery cells included in a battery module.

However, in foil breakage inspection according to the related art, a method of stopping a line of a battery formation process and inspecting foil breakage of a battery cell by adding an additional inspection process may be used.

However, the foil breakage inspection method according to the related art may be a method in which an inspection process is added in the middle of the battery formation process, such that a line may need to be temporarily stopped during the battery formation process. Thus, many semi-finished battery cells in production may be put on hold.

In addition, as the battery formation process progresses, a current path may be temporarily formed before a battery cell is completed, and thus it may be difficult to accurately detect internal resistance and delta internal resistance.

### SUMMARY

According to an aspect of the present disclosure,

there is provided an early diagnosis apparatus for foil breakage of a battery, the early diagnosis apparatus including a resistance measurer configured to measure an internal resistance of each of a plurality of battery cells included in a battery tray output from a battery assembly process when a point in time of an inspection start is reached after battery assembly is completed, during a pause period between a battery assembly process and a battery formation process, and a foil breakage inspector configured to calculate a delta internal resistance, based on the internal resistance received from the resistance measurer, and to inspect whether foil breakage is present in each of the plurality of battery cells, based on the delta internal resistance.

According to another aspect of the present disclosure, there is provided an early diagnosis method for foil breakage of a the early diagnosis method including an inspection start determination operation of determining, by a foil breakage early diagnosis apparatus, a point in time of an inspection start by determining whether a preset inspection start time has elapsed when an assembly process is completed by a battery assembly facility of a battery assembly process, a resistance measurement operation of measuring, by the foil breakage early diagnosis apparatus, an internal resistance of each of a plurality of battery cells included in a battery tray, using a resistance measurer, when the inspection start time is determined in the inspection start determination operation, a delta internal resistance calculation operation of calculating, by the foil breakage early diagnosis apparatus, a delta internal resistance, based on the internal resistance measured in the resistance measurement operation, and a foil breakage determination operation of determining, by the foil breakage early diagnosis apparatus, whether foil breakage is present in each of the plurality of battery cells included in the battery tray, based on the delta internal resistance.

In addition, the aspects of the present disclosure are not limited to the above-described aspects, and another aspect may be additionally understood in the process described below.

According to the aspects of the present disclosure, foil breakage may be detected using an internal resistance and a delta internal resistance of each of a plurality of battery cells included in a battery tray before a battery formation process is stabilized during a pause period when battery assembly is completed in a battery assembly process.

In addition, early diagnosis may be performed in a pause period that is an early stage of entry into the battery formation process, thereby preventing issues according to the related art.

However, the various and beneficial advantages and effects of the present disclosure are not restricted to those set forth herein, and will be more easily understood in the process of describing specific embodiments.

### BRIEF DESCRIPTION OF DRAWINGS

Certain aspects, features, and advantages of the present disclosure are illustrated by the following detailed description with reference to the accompanying drawings.

FIG. 1 is a schematic diagram illustrating an early diagnosis apparatus for foil breakage of a battery according to an embodiment of the present disclosure.

FIG. 2 is an exemplary diagram illustrating measurement of a resistance of a battery tray.

FIG. 3 is another exemplary diagram illustrating measurement of a resistance of a battery tray.

FIGS. 4A and 4B are exemplary diagrams of measurement of a resistance of a battery tray in a transport means between a battery assembly process and a battery formation process.

FIG. 5A, 5B, 5C, and 5D are exemplary diagrams of measurement of a resistance of a battery tray in an aging room, an initial section of a battery formation process.

FIG. 6 is an exemplary diagram illustrating a foil breakage inspector.

FIG. 7 is an exemplary diagram illustrating an inspection start determination unit.

FIG. 8 is an explanatory diagram illustrating an assembly process completion signal and an inspection start signal related to an inspection start determination unit.

FIG. 9 is an exemplary diagram illustrating a resistance storage unit.

FIG. 10 is an exemplary diagram illustrating an internal resistance memory.

FIG. 11 is an exemplary diagram illustrating a delta internal resistance calculation unit.

FIG. 12A is a distribution graph illustrating an aging time-internal resistance relationship, and FIG. 12B is a distribution graph illustrating an aging time-delta internal resistance relationship.

FIG. 13 is an exemplary diagram illustrating a foil breakage determination unit.

FIG. 14 is an exemplary diagram illustrating foil breakage of a battery cell.

FIG. 15 is a flowchart illustrating an early diagnosis method for a foil breakage of a battery according to an embodiment of the present disclosure.

FIG. 16 is an exemplary diagram illustrating an assembly process completion determination operation.

FIG. 17 is an exemplary diagram illustrating a resistance measurement operation.

FIG. 18 is an exemplary diagram illustrating a delta internal resistance calculation operation.

FIG. 19 is an exemplary diagram illustrating a foil breakage inspection operation.

FIG. 20 is an exemplary diagram illustrating experimental data on foil breakage detection power (detection capability).

### DETAILED DESCRIPTION

Hereinafter, embodiments of the present disclosure will be further described with reference to specific experimental examples. Examples and comparative examples included in the experimental examples are merely illustrative of the present disclosure and do not limit the appended claims, and it is clear to those skilled in the art that various changes and modifications to embodiments can be made within the scope and technical idea of the present disclosure, and it is obvious that such modifications and modifications belong to the appended claims.

Various modifications may be made to the embodiments. Here, the embodiments should not be construed as being limited to the present disclosure and should be understood to include all changes, equivalents, and replacements within the idea and the technical scope of the disclosure.

The terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component. The term “and/or” may include combinations of a plurality of related described items or any of a plurality of related described items.

The terminology used herein is for the purpose of describing particular embodiments only and is not to be limiting of the embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in this disclosure, specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein, including technical or scientific terms, have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

Hereinafter, embodiments of the present disclosure will be described in more detail with reference to the accompanying drawings.

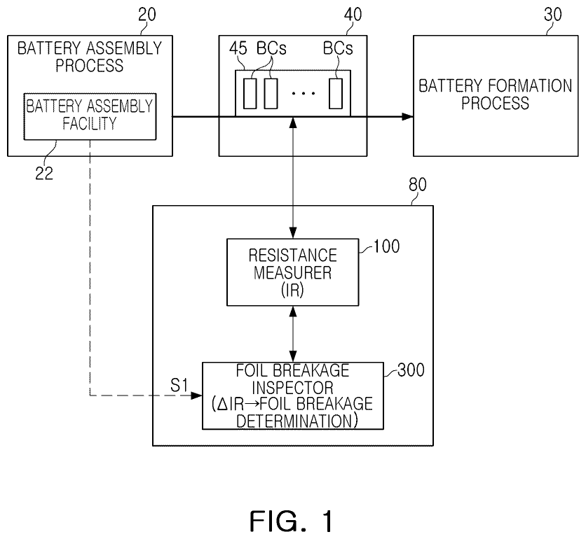

FIG. 1 is a schematic diagram illustrating a foil breakage early diagnosis apparatus of a battery according to an embodiment of the present disclosure.

Referring to FIG. 1, an early diagnosis apparatus for foil breakage of a battery (hereinafter referred to as a “foil breakage early diagnosis apparatus 80”) according to an embodiment of the present disclosure may include a resistance measurer 100 and a foil breakage inspector 300.

The resistance measurer 100 may measure an internal resistance IR of each of a plurality of battery cells BCs included in a battery tray 45 output from a battery assembly process 20 during a pause period 40 between a battery assembly process 20 and a battery formation process 30.

For example, the resistance measurer 100 may measure the internal resistance IR based on changes in charging current and charging voltage in each of the plurality of battery cells BCs included in the battery tray 45, or may measure the internal resistance IR based on changes in discharge current and discharge voltage.

When the inspection start time TT is reached, the foil breakage inspector 300 may calculate a delta internal resistance ΔIR, based on the internal resistance IR received from the resistance measurer 100, and may inspect, based on the delta internal resistance ΔIR, whether foil breakage is present in each of the plurality of battery cells BCs.

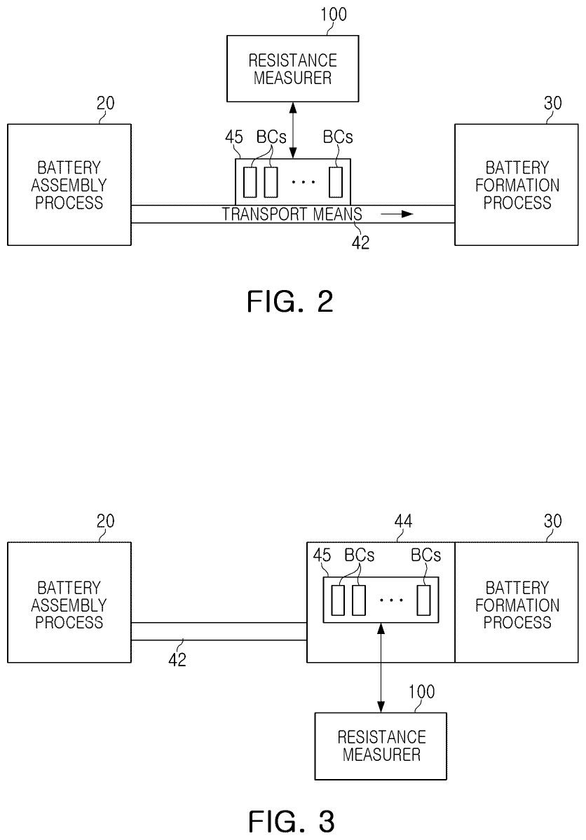

For example, the pause period 40 between the battery assembly process 20 and the battery formation process 30 may be a pause period time for battery stabilization after the battery assembly process is completed and before the battery formation process is started. For example, the pause period 40 may correspond to a pause period time during which a transport means 42, transporting the battery tray 45, is temporarily stopped to diagnose foil breakage of each of the plurality of battery cells included in the battery tray 45. Alternatively, the pause period 40 may correspond to a pause period time during which the battery tray 45 is stored in an aging room 44 for aging each of the plurality of battery cells included in the battery tray 45 before entry into the battery formation process 30, which will be described with reference to FIGS. 2 and 3.

A battery cell of the present disclosure may be applied to a pouch cell, a cylindrical cell, a prismatic cell, or the like. A battery device to which the battery cell of the present disclosure is applied may be a battery module or a battery pack, and is not limited to a specific structure or type of battery device, and may correspond to a battery, requiring measurement of an insulation voltage, among rechargeable batteries.

In the drawings of the present disclosure, unnecessary repeated descriptions of components having the same reference numeral and the same function may be omitted, and differences between the drawings may be described.

FIG. 2 is an exemplary diagram illustrating measurement of a resistance of a battery tray.

Referring to FIG. 2, the resistance measurer 100 may measure the internal resistance IR of each of the plurality of battery cells BCs included in the battery tray 45 being transported by the transport means 42 between the battery assembly process 20 and the battery formation process 30.

For example, the transport means 42 may be temporarily stopped for diagnosis of foil breakage, and the resistance measurer 100 may be electrically connected to the plurality of battery cells BCs to perform internal measurement at a point in time TT of an inspection start at which the transport means 42 is temporarily stopped. For example, the transport means 42 may include a conveyor belt.

FIG. 3 is another exemplary diagram illustrating measurement of a resistance of a battery tray.

Referring to FIG. 3, the resistance measurer 100 may measure the internal resistance IR of each of the plurality of battery cells BCs included in the battery tray 45 stored in the aging room 44 before entry into the battery formation process 30.

For example, the aging room 44 may include a space for storing a plurality of battery trays 45 for stabilization of an assembled battery cell before the battery formation process is started in earnest after the battery assembly process is completed. At a preset inspection start time TT, the resistance measurer 100 may be electrically connected to the plurality of battery cells BCs included in the battery tray 45 to perform internal measurement.

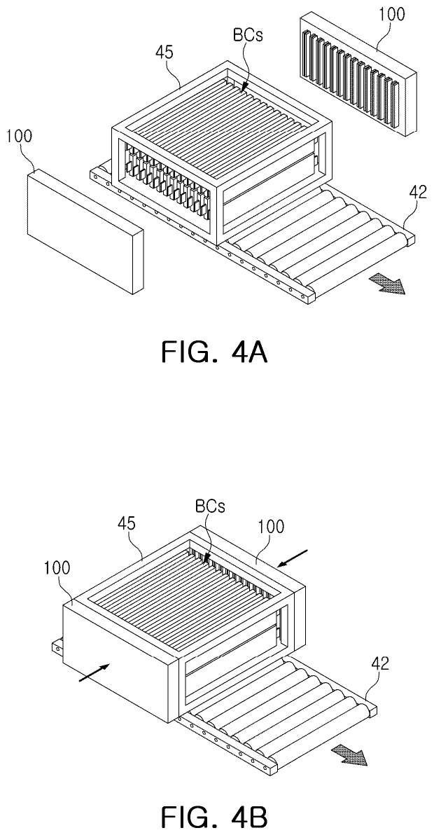

FIGS. 4A and 4B are exemplary diagrams of measurement of resistance of a battery tray in a transport means between a battery assembly process and a battery formation process.

Referring to FIG. 4A, when the battery tray 45 including the plurality of battery cells BCs to be inspected is transported to a position, in which inspection is to be performed, by the transport means 42, the transport means 42 may be temporarily stopped.

Referring to FIG. 4B, when the transport means 42 is temporarily stopped, the resistance measurer 100 may be electrically connected to both sides of each of the plurality of battery cells BCs of the battery tray 45 to be inspected, and the internal resistance IR may be measured.

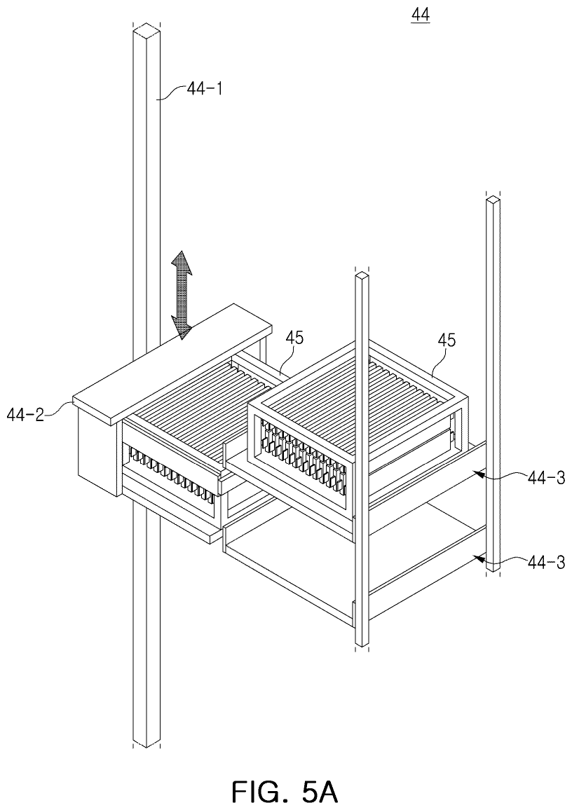

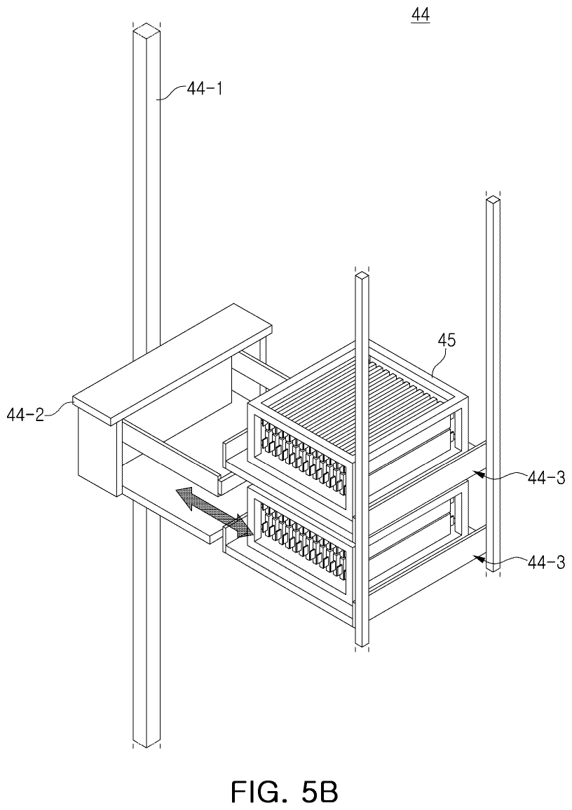

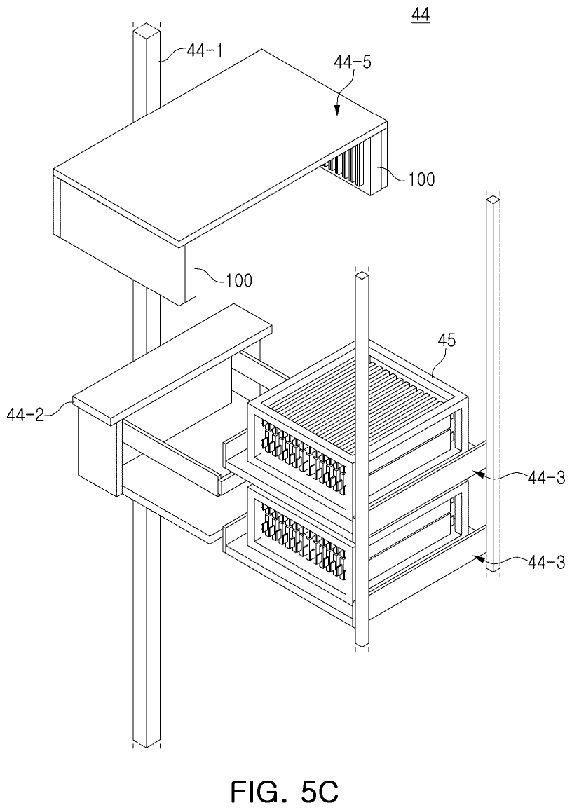

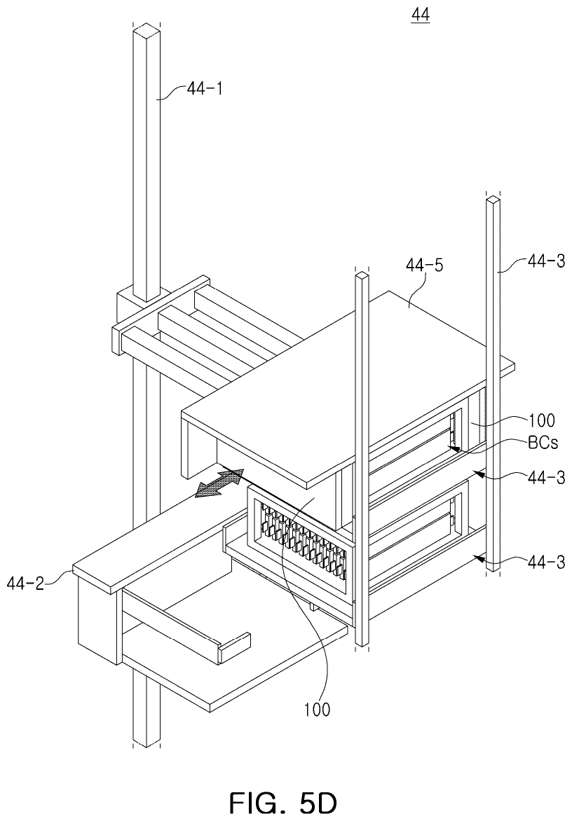

FIG. 5A, 5B, 5C, and 5D are exemplary diagrams of measurement of a resistance of a battery tray in an aging room, an initial section of a battery formation process.

Referring to FIGS. 5A and 5B, the battery tray 45, transported to the aging room 44 by the transportation means, may be put into a corresponding aging rack 44-3 by a stack crane 44-2 moving along a crane rail 44-1.

Referring to FIGS. 5C and 5D, when a corresponding battery tray 45 is put into a corresponding aging rack 44-3, the stack crane 44-2 may move backwardly to be in a standby position, and an inspection housing 44-5, in which the resistance measurer 100 for inspection is disposed, may move along the crane rail 44-1, may approach the corresponding battery tray 45 of the corresponding aging rack 44-3, may be electrically connected to both sides of each of the plurality of battery cells BCs of the corresponding battery tray 45, and may measure the internal resistance IR.

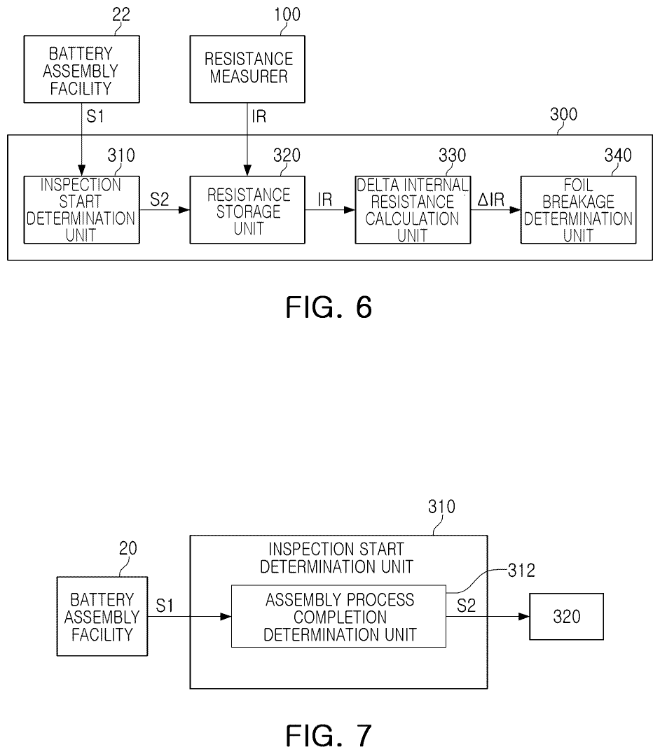

FIG. 6 is an exemplary diagram illustrating a foil breakage inspector.

Referring to FIG. 6, the foil breakage inspector 300 may include an inspection start determination unit 310, a resistance storage unit 320, a delta internal resistance calculation unit 330, and a foil breakage determination unit 340.

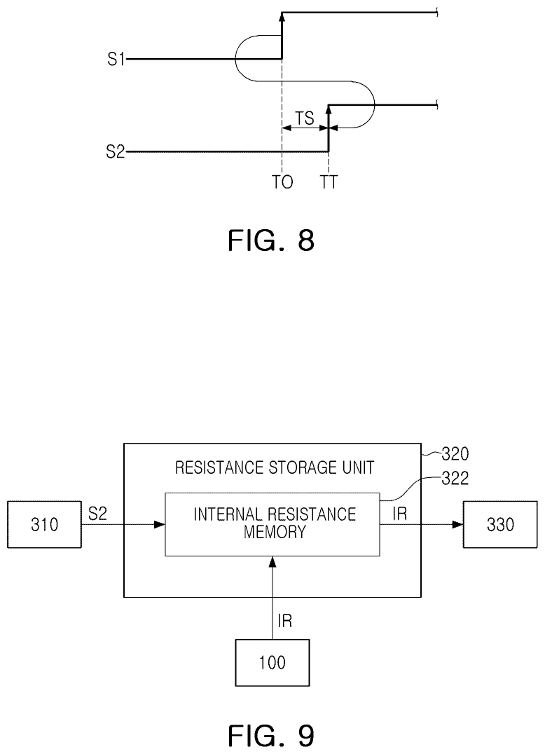

When an assembly process is completed by a battery assembly facility 22 of the battery assembly process 20, the inspection start determination unit 310 may determine whether a preset inspection start time TT has elapsed to determine a point in time of an inspection start. For example, the inspection start determination unit 310 may determine completion of the assembly process, based on an assembly process completion signal S1 received from the battery assembly facility 22. At the point in time TT of an inspection start, a point in time at which a preset time has elapsed from a point in time at which the assembly process is completed, the inspection start determination unit 310 may generate an inspection start signal S2 including inspection start information and output the inspection start signal S2 to the resistance storage unit 320, which will be described with reference to FIGS. 7 and 8.

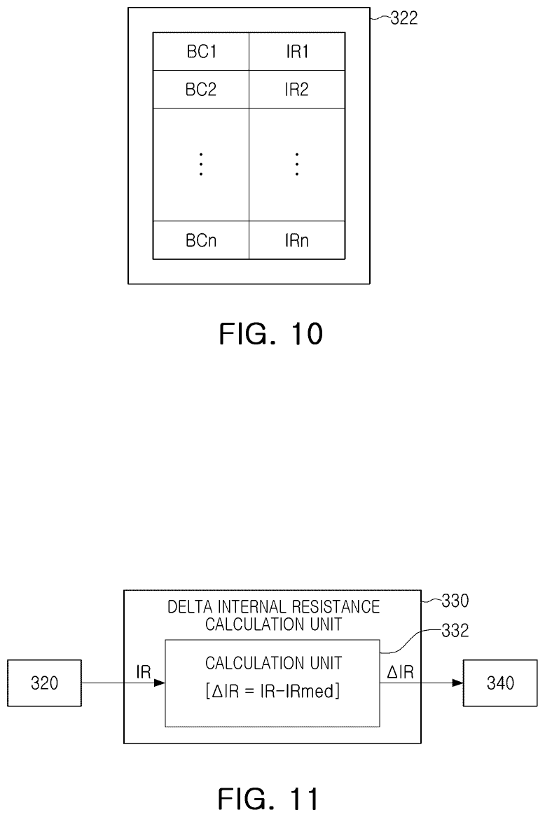

When the inspection start time TT is determined by the inspection start determination unit 310, the resistance storage unit 320 may store the internal resistance IR received from the resistance measurer 100. For example, when the inspection start time TT is determined based on the inspection start signal S2 received from the inspection start determination unit 310, the resistance storage unit 320 may store the internal resistance IR of each of the plurality of battery cells BCs, received from the resistance measurer 100, which will be described with reference to FIGS. 9 and 10.

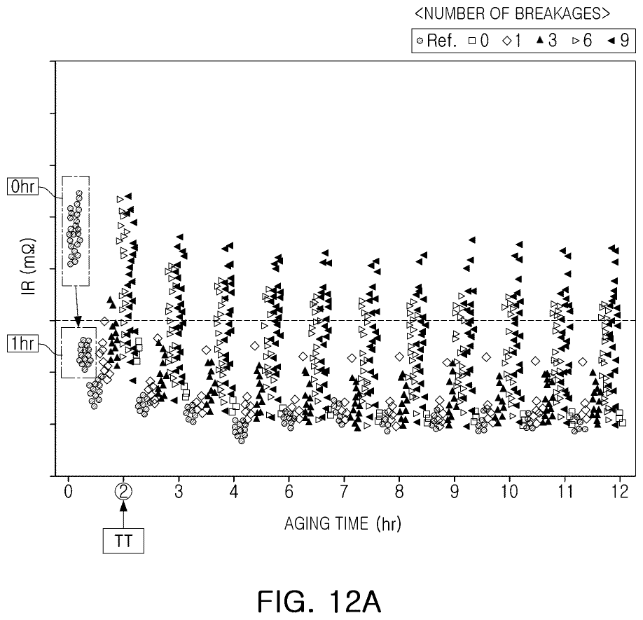

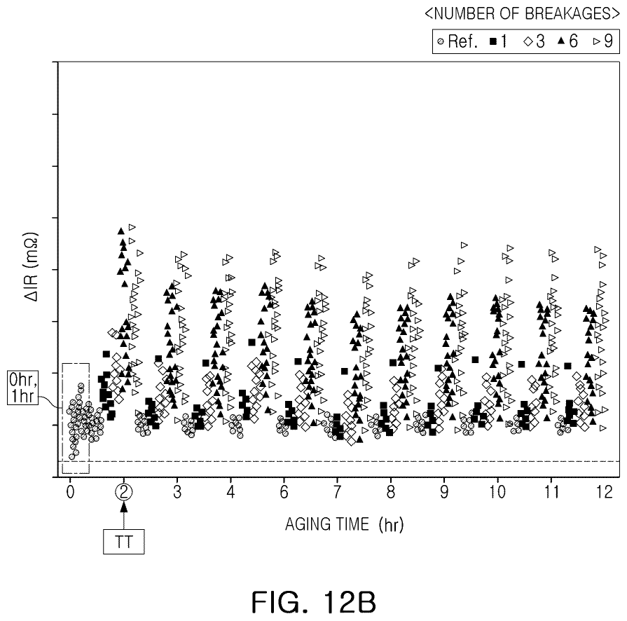

The delta internal resistance calculation unit 330 may calculate a delta internal resistance ΔIR, based on the internal resistance IR of the resistance storage unit 320. For example, the delta internal resistance calculation unit 330 may calculate the delta internal resistance ΔIR using the internal resistance IR of each of the plurality of battery cells BCs and an internal resistance intermediate value IRmed for all of the plurality of battery cells BCs in the battery tray, which will be described with reference to FIGS. 11, 12A, and 12B.

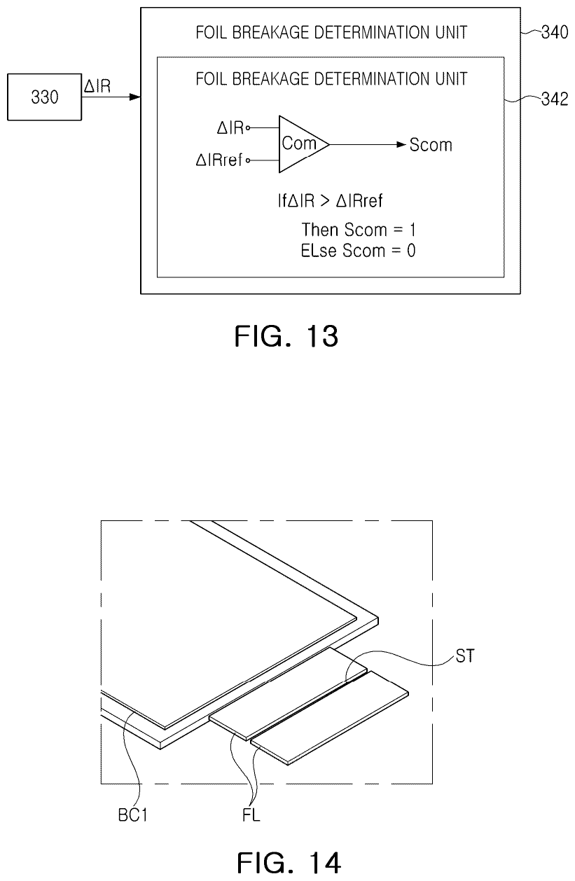

The foil breakage determination unit 340 may determine, based on the delta internal resistance ΔIR, whether foil breakage is present in each of the plurality of battery cells BCs included in the battery tray 45. For example, the foil breakage determination unit 340 may compare resistance ΔIR with a preset delta the delta internal internal resistance reference value ΔIRref to determine whether foil breakage is present in each of the battery cells BCs, which will be described with reference to FIG. 13.

In the present disclosure, each of the inspection start determination unit 310, the resistance storage unit 320, the delta internal resistance calculation unit 330, and the foil breakage determination unit 340 may be implemented as hardware or software in at least one integrated circuit (IC) embedded in the foil breakage inspector 300, but the present disclosure is not limited thereto.

In addition, each of inspection start the determination unit 310, the resistance storage unit 320, the delta internal resistance calculation unit 330, and the foil breakage determination unit 340 may be implemented as an individual processor or as an integrated processor, but the present disclosure is not limited thereto.

FIG. 7 is an exemplary diagram illustrating an inspection start determination unit, and FIG. 8 is an explanatory diagram illustrating an assembly process completion signal and an inspection start signal related to an inspection start determination unit.

Referring to FIG. 7, the inspection start determination unit 310 may include an assembly process completion determination unit 312.

For example, at a point in time at which the battery assembly process is completed, the assembly process completion determination unit 312 may generate an inspection start signal S2 by determining a point in time TT of an inspection start at which a preset time TS has elapsed from an assembly process completion time TO, based on the assembly process completion signal S1 received from the battery assembly facility 22 for diagnosis start.

Referring to FIG. 8, a level of the assembly process completion signal S1, generated by the assembly process completion determination unit 312, may transition from a low level to a high level at a point in time at which the battery assembly process is completed. In this case, the assembly process completion determination unit 312 may determine a point in time at which level of the assembly process completion signal S1 is a high level as an assembly process completion point in time.

In addition, a level of the inspection start signal S2, generated by the assembly process completion determination unit 312, may transition from a low level to a high level when a preset time TS has elapsed from the assembly process completion point in time at which the level of the assembly process completion signal S1 transitions to a high level.

In the present disclosure, a case has been described in which the levels of the assembly process completion signal S1 and the inspection start signal S2 respectively transition from a low level to a high level at the completion time TO of the battery assembly process and the inspection start time TT, but the case is for ease of description and understanding, and the present disclosure is not limited thereto. Unlike the above example, the levels of the assembly process completion signal S1 and the inspection start signal S2 may respectively transit from a high level to a low level at the completion time TO of the battery assembly process and the inspection start time TT. For example, the high level and the low level may be voltage levels, and may be logic “1” and logic “0,” respectively.

FIG. 9 is an exemplary diagram illustrating a resistance storage unit.

Referring to FIG. 9, the resistance storage unit 320 may include an internal resistance memory 322.

For example, the internal resistance memory 322 may receive and store the internal resistance IR of each of the plurality of battery cells BCs included in the battery tray 45 when the point in time TT of an inspection start is determined based on the inspection start signal S2 received from the inspection start determination unit 310.

For example, the internal resistance memory 322 may include a plurality of internal resistors IR respectively corresponding to the plurality of battery cells BCs included in the battery tray 45.

FIG. 10 is an exemplary diagram illustrating an internal resistance memory.

Referring to FIG. 10, for example, when the battery tray 45 includes a first battery cell BC1, a second battery cell BC2, . . . , and an n-th battery cell BCn, the internal resistance memory 322 may include a first internal resistor IR1, a second internal resistor IR2, . . . , and an n-th internal resistor IRn respectively corresponding to the first battery cell BC1, the second battery cell, . . . , and the n-th battery cell BCn. For example, each of the first, second to nth internal resistors IR1 and IR2 to IRn may be information on a magnitude of internal resistance.

FIG. 11 is an exemplary diagram illustrating a delta internal resistance calculation unit.

Referring to FIG. 11, the delta internal resistance calculation unit 330 may include a calculation unit 332.

For example, the calculation unit 332 may calculate a delta internal resistance ΔIR by subtracting the internal resistance IR from the resistance measurer 100, and the internal resistance intermediate value IRmed for all of the plurality of battery cells BCs included in the battery tray 45.

For example, the delta internal resistance ΔIR may be calculated as indicated in Equation 1 below.

$$Δ IR = IR - IRmed \qquad [ Equation 1 ]$$

In Equation 1, ΔIR may be a delta internal resistance, IR may be an internal resistance, and IRmed may be an internal resistance intermediate value. The internal resistance intermediate value IRmed may be a value between a minimum value and a maximum value, among values of a plurality of internal resistances respectively corresponding to the plurality of battery cells BCs included in the corresponding battery tray 45.

FIG. 12A is a distribution graph illustrating an aging time-internal resistance relationship, and FIG. 12B is a distribution graph illustrating an aging time-delta internal resistance relationship.

The distribution graph illustrated in FIG. 12A indicates a magnitude of internal resistance by the number of breakages according to an aging time in coordinates of an aging time that is a horizontal axis and a magnitude of internal resistance that is a vertical axis.

Referring to the distribution graph illustrated in FIG. 12A, it may be seen that a magnitude of reference resistance decreases without foil breakage when an aging time is from 0 hour (hr) to 1 hour (hr). When the aging time is 2 hours (hr), it may be seen that the magnitude of internal resistance is variously and widely distributed according to the number of breakages (1, 2, 3, . . . ). In addition, it may be seen that distribution of the magnitude of internal resistance narrows as the aging time increases to 3 hours, 4 hours, or the like.

In addition, referring to FIG. 12A, when the aging time is 2 hours, the magnitude of internal resistance is relatively widely distributed according to the number of foil breakages. Thus, it may be seen that foil breakage may be accurately detected when the aging time is 2 hours.

The distribution graph illustrated in FIG. 12B indicates a magnitude of delta internal resistance by the number of breakages according to an aging time in coordinates of an aging time that is a horizontal axis and a magnitude of internal resistance that is a vertical axis.

Referring to the distribution graph illustrated in FIG. 12B, it may be seen that a magnitude of reference delta resistance is in a low state without foil breakage when an aging time is from 0 hours (hr) to 1 hour (hr). When the magnitude of delta internal resistance is variously and widely distributed according to the number of breakages (1, 2, 3, . . . ). In addition, it may be seen that distribution of the magnitude of delta internal resistance narrows as the aging time increases to 3 hours, 4 hours, or the like.

In addition, referring to FIG. 12B, when the aging time is 2 hours, the magnitude of delta internal resistance may be relatively widely distributed according to the number of foil breakages. Thus, it may be seen that foil breakage may be accurately detected using internal resistance when the aging time is 2 hours.

FIG. 13 is an exemplary diagram illustrating a foil breakage determination unit.

Referring to FIG. 13, the foil breakage determination unit 340 may include a foil breakage comparison unit 342.

For example, the foil breakage comparison unit 342 may compare a delta internal resistance ΔIR from the delta internal resistance calculation unit 330 and a preset delta internal resistance reference value ΔIRref to each other with respect to each of the plurality of battery cells BCs included in the battery tray 45, and may output a determination signal Scom having a level according to a comparison result.

For example, when the delta internal resistance ΔIR is greater than the delta internal resistance reference value ΔIRref, the foil breakage comparison unit 342 may output a determination signal Scom having a high level (logic “1”). When the delta internal resistance ΔIR is not greater than the delta internal resistance reference value ΔIRref, the foil breakage comparison unit 342 may output a determination signal Scom having a low level (logic “0”).

FIG. 14 is an exemplary diagram illustrating foil breakage of a battery cell.

Referring to one battery cell BC1 illustrated in FIG. 14, an example is illustrated in which an electrode foil FL disposed at one side of the battery cell BC1 is broken (ST). As described above, when the electrode foil FL of the battery cell BC1 is broken (ST), a magnitude of internal resistance may increase, or a magnitude of delta internal resistance may increase.

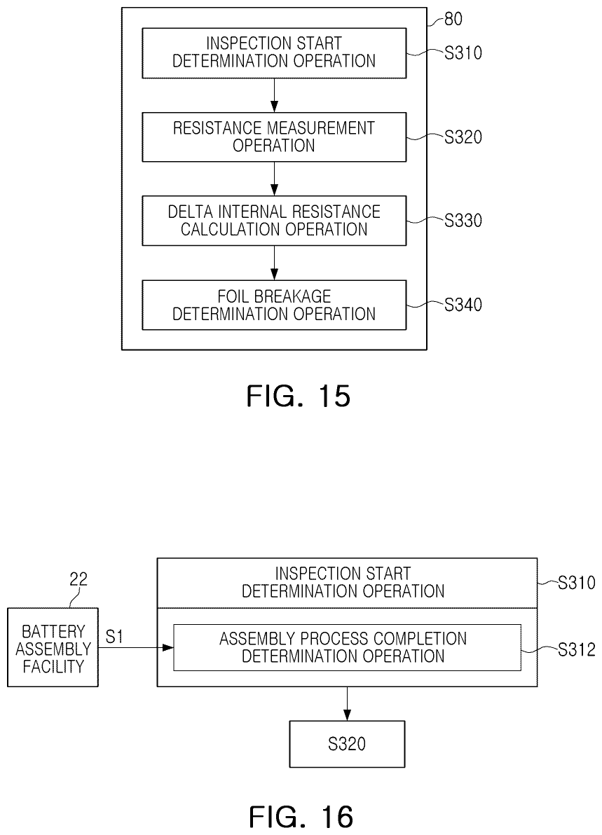

Hereinafter, an early diagnosis method for foil breakage of a battery will be described with reference to FIGS. 15 and 22. In the present disclosure, a description of the early diagnosis method for foil breakage of a battery and a description of the early diagnosis apparatus for foil breakage of a battery provided with reference to FIGS. 1 to 14 may complement each other or may be applied in common, unless the descriptions are mutually exclusive. Accordingly, a repeated description may be omitted.

FIG. 15 is a flowchart illustrating an early diagnosis method for a foil breakage of a battery according to an embodiment of the present disclosure.

Referring to FIG. 15, the early diagnosis method for foil breakage of a battery according to an embodiment of the present disclosure may be implemented by foil breakage early diagnosis apparatus 80, and may include an inspection start determination operation S310, a resistance measurement operation S320, a delta internal resistance calculation operation S330, and a foil breakage determination operation S340.

In the inspection start determination operation S310, the foil breakage early diagnosis apparatus 80 may determine a point in time of an inspection start by determining whether a preset inspection start time TT has elapsed when an assembly process is completed by a battery assembly facility.

In the resistance measurement operation S320, when the inspection start time TT is determined in the inspection start determination operation S310, the foil breakage early diagnosis apparatus 80 may measure an internal resistance IR of each of the plurality of battery cells BCs included in the battery tray 45.

In the delta internal resistance calculation operation S330, the foil breakage early diagnosis apparatus 80 may calculate a delta internal resistance ΔIR, based on the internal resistance IR measured in the resistance measurement operation S320.

In the foil breakage determination operation S340, the foil breakage early diagnosis apparatus 80 may determine, based on the delta internal resistance ΔIR, whether foil breakage is present in each of the plurality of battery cells BCs included in the battery tray 45.

FIG. 16 is an exemplary diagram illustrating an assembly process completion determination operation.

Referring to FIG. 16, the inspection start determination operation S310 may include an assembly process completion determination operation S312.

For example, in the assembly process completion determination operation S312, the foil breakage early diagnosis apparatus 80 may generate an inspection start signal S2 by determining a point in time TT of an inspection start at which a preset time TS has elapsed from an assembly process completion time TO, based on the assembly process completion signal S1 received from the battery assembly facility 22 for diagnosis start.

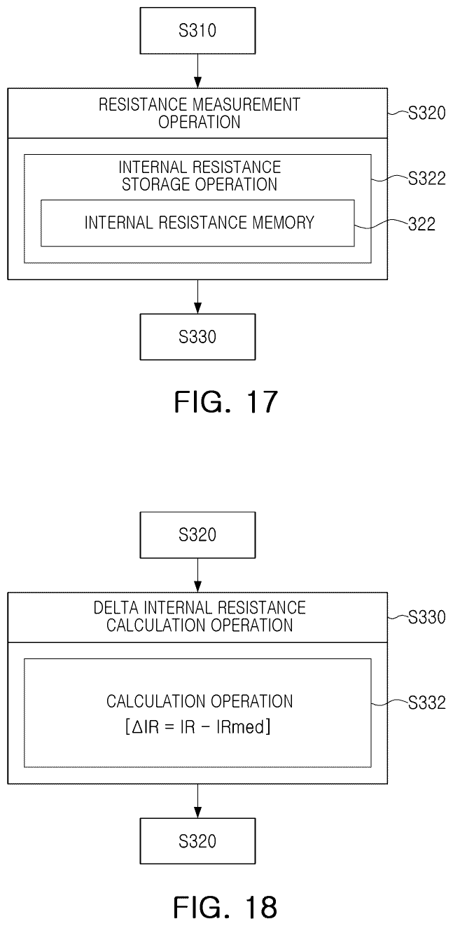

FIG. 17 is an exemplary diagram illustrating a resistance measurement operation.

Referring to FIG. 17, the resistance measurement operation S320 may include an internal resistance storage operation S322.

For example, in the internal resistance storage operation S322, the foil breakage early diagnosis apparatus 80 may receive the internal resistance IR of each of the plurality of battery cells BCs included in the battery tray 45, and may store the internal resistance IR in the internal resistance memory 322.

FIG. 18 is an exemplary diagram illustrating a delta internal resistance calculation operation.

Referring to FIG. 18, the delta internal resistance calculation operation S330 may include a calculation operation S332.

For example, the foil breakage early diagnosis apparatus 80 may calculate a delta internal resistance ΔIR by subtracting the internal resistance IR from the resistance measurer 100, and the internal resistance intermediate value IRmed for all of the plurality of battery cells BCs included in the battery tray 45.

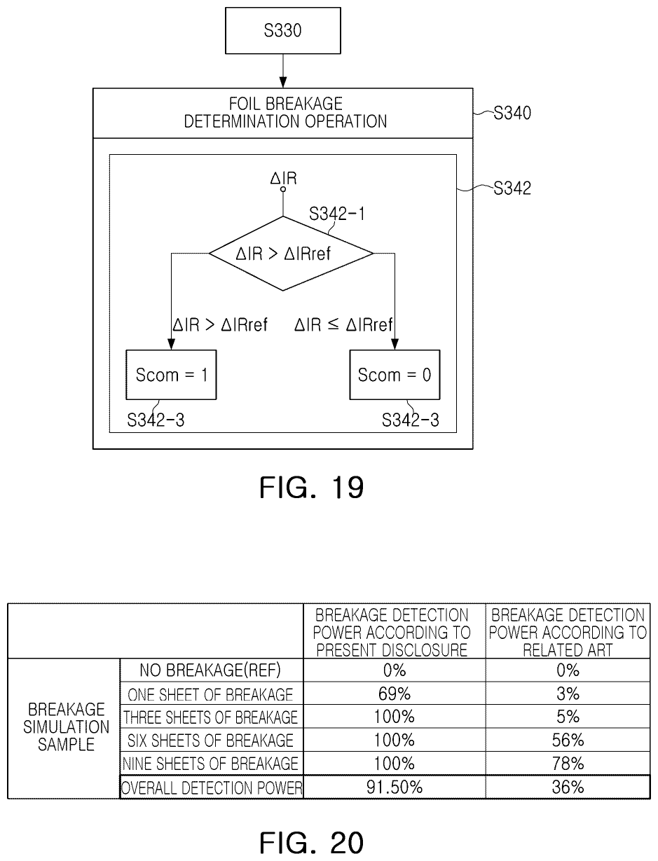

FIG. 19 is an exemplary diagram illustrating a foil breakage inspection operation.

Referring to FIG. 19, the foil breakage determination operation S340 may include a foil breakage comparison operation S342.

For example, in the foil breakage comparison operation S342, the foil breakage early diagnosis apparatus 80 may compare the delta internal resistance ΔIR and a preset delta internal resistance reference value ΔIRref to each other with respect to each of the plurality of battery cells (BCs) included in the battery tray 45, and may output a determination signal Scom having a level according to a comparison result.

For example, in the foil breakage comparison operation S342, the foil breakage early diagnosis apparatus 80 may output a determination signal Scom having a high level (logic “1”) when the delta internal resistance ΔIR is greater than the delta internal resistance reference value ΔIRref, and may output a determination signal Scom having a low level (logic “0”) when the delta internal resistance ΔIR is not greater than the delta internal resistance reference value ΔIRref.

FIG. 20 is an exemplary diagram illustrating experimental data on foil breakage detection power (detection capability).

Experimental data on a detection rate, illustrated in FIG. 20, may be experimental result data obtained by using a simulation sample of 100 battery cells having one sheet of foil breakage among forty foil sheets, a simulation sample of 100 battery cells having three sheets of foil breakage among forty foil sheets, a simulation sample of 100 battery cells having six sheets of foil breakage among forty foil sheets, a simulation sample of 100 battery cells having nine sheets of foil breakage among forty foil sheets, and a simulation sample having no foil breakage among forty foil sheets, as a reference REF.

Referring to FIG. 20, Referring to FIG. 20, a breakage detection power using a foil breakage diagnosis method according to the related art may be 3%, 5%, 56%, and 75%, respectively, with respect to one sheet of foil breakage, three sheets of foil breakage, six sheets of foil breakage, and nine sheets of foil breakage, and an overall detection power may be 36%, However, a breakage detection power according to the present disclosure may be 69%, 100%, 100%, and 100%, respectively, with respect to one sheet of foil breakage, three sheets of foil breakage, six sheets of foil breakage, and nine sheets of foil breakage, and an overall detection power may be 91.50%. Accordingly, it may be seen that the overall detection power according to the present disclosure is higher than the overall detection power of 36% according to the related art.

Only specific examples of implementations of certain embodiments are described. Variations, improvements and enhancements of the disclosed embodiments and other embodiments may be made based on the disclosure of this patent document.

What is claimed is:

1. An early diagnosis apparatus for foil breakage of a battery, the early diagnosis apparatus comprising:
a resistance measurer configured to measure an internal resistance of each of a plurality of battery cells included in a battery tray output from a battery assembly process when a point in time of an inspection start is reached after battery assembly is completed, during a pause period between a battery assembly process and a battery formation process; and
a foil breakage inspector configured to calculate a delta internal resistance, based on the internal resistance received from the resistance measurer, and to inspect whether foil breakage is present in each of the plurality of battery cells, based on the delta internal resistance.

2. The early diagnosis apparatus of claim 1, wherein the resistance measurer is configured to measure the internal resistance of each of the plurality of battery cells included in the battery tray being transported by a transport means between the battery assembly process and the battery formation process.

3. The early diagnosis apparatus of claim 1, wherein the resistance measurer is configured to measure the internal resistance of each of the plurality of battery cells included in the battery tray stored in an aging room before entry into the battery formation process.

4. The early diagnosis apparatus of claim 1, wherein the foil breakage inspector includes:
an inspection start determination unit configured to determine a point in time of an inspection start by determining whether a preset inspection start time has elapsed when an assembly process is completed by a battery assembly facility of the battery assembly process;
a resistance storage unit configured to store the internal resistance received from the resistance measurer when the inspection start time is determined by the inspection start determination unit;
a delta resistance internal calculation unit configured to calculate a delta internal resistance, based on the internal resistance of the resistance storage unit; and
a foil breakage determination unit configured to determine whether foil breakage is present in each of the plurality of battery cells included in the battery tray, based on the delta internal resistance.

5. The early diagnosis apparatus of claim 4, wherein the inspection start determination unit includes an assembly process completion determination unit configured to determine, at a point in time at which the battery assembly process is completed, a point in time of an inspection start at which a preset time has elapsed from the point in time at which the assembly process is completed, based on an assembly process completion signal received from a battery assembly facility for diagnosis start, to generate an inspection start signal.

6. The early diagnosis apparatus of claim 4, wherein the resistance storage unit includes an internal resistance memory configured to receive and store the internal resistance of each of the plurality of battery cells included in the battery tray.

7. The early diagnosis apparatus of claim 4, wherein the delta internal resistance calculation unit includes a calculation unit configured to calculate the delta internal resistance by subtracting the internal resistance from the resistance measurer, and an internal resistance intermediate value for all of the plurality of battery cells included in the battery tray.

8. The early diagnosis apparatus of claim 4, wherein the foil breakage determination unit includes a foil breakage comparison unit configured to compare the delta internal resistance and a preset delta internal resistance reference value to each other with respect to each of the plurality of battery cells included in the battery tray to output a determination signal having a level according to a comparison result.

9. An early diagnosis method for foil breakage of a battery, the early diagnosis method comprising:
an inspection start determination operation of determining, by a foil breakage early diagnosis apparatus, a point in time of an inspection start by determining whether a preset inspection start time has elapsed when an assembly process is completed by a battery assembly facility of a battery assembly process;
a resistance measurement operation of measuring, by the foil breakage early diagnosis apparatus, an internal resistance of each of a plurality of battery cells included in a battery tray, using a resistance measurer, when the inspection start time is determined in the inspection start determination operation;
a delta internal resistance calculation operation of calculating, by the foil breakage early diagnosis apparatus, a delta internal resistance, based on the internal resistance measured in the resistance measurement operation; and
a foil breakage determination operation of determining, by the foil breakage early diagnosis apparatus, whether foil breakage is present in each of the plurality of battery cells included in the battery tray, based on the delta internal resistance.

10. The early diagnosis method of claim 9, wherein the inspection start determination operation includes an assembly process completion determination operation of determining, at a point in time at which the battery assembly process is completed, a point in time of an inspection start at which a preset time has elapsed from the point in time at which the assembly process is completed, based on an assembly process completion signal received from a battery assembly facility for diagnosis start, to generate an inspection start signal.

11. The early diagnosis method of claim 9, wherein the resistance measurement operation is an internal resistance storage operation of receiving the internal resistance of each of the plurality of battery cells included in the battery tray, and storing the internal resistance in an internal resistance memory.

12. The early diagnosis method of claim 9, wherein the delta internal resistance calculation operation includes a calculation operation of calculating the delta internal resistance by subtracting the internal resistance from the resistance measurer, and an internal resistance intermediate value for all of the plurality of battery cells included in the battery tray.

13. The early diagnosis method of claim 9, wherein the foil breakage determination operation includes a foil breakage comparison operation of comparing the delta internal resistance and a preset delta internal resistance reference value each other with respect to each of the plurality of battery cells included in the battery tray to output a determination signal having a level according to a comparison result.
